(19) United States
(12) Patent Application Publication
(10) Pub. No.: US 2025/0336785 A1
(43) Pub. Date: Oct. 30, 2025

(54) DOUBLE-SIDED HIGH-POWER MODULES WITH AIR CAVITY

(71) Applicant: Qorvo US, Inc., Greensboro, NC (US)

(72) Inventors: Peter Haase, Richardson, TX (US); MD Hasnine, Richardson, TX (US)

(21) Appl. No.: 19/082,359

(22) Filed: Mar. 18, 2025

Related U.S. Application Data
(60) Provisional application No. 63/640,528, filed on Apr. 30, 2024.

(51) Int. Cl. H01L 23/498; H01L 21/56; H01L 23/043; H01L 23/29

(52) U.S. Cl. CPC H01L 23/49816; H01L 21/565; H01L 23/043; H01L 23/29; H01L 23/49827

(57) ABSTRACT

Double-sided high-power modules with air cavities are disclosed. In one aspect, a module may have a metallization layer having a high-power die on a first side and other components encased in mold material on a second side opposite the first side. Conductors are provided that couple metal conductors in the metallization layer through the mold to an external surface of the mold material such that the module may be electrically coupled to a substrate such as a printed circuit board or the like. By placing components on both sides of the metallization layer, the overall x-y dimensions of the module may be reduced.

### PRIORITY APPLICATION

The present application claims priority to U.S. Provisional Patent Application Ser. No. 63/640,528, entitled DOUBLE-SIDED HIGH-POWER MODULES WITH AIR CAVITY, filed on Apr. 30, 2024, the contents of which is hereby incorporated by reference in its entirety.

### BACKGROUND

### I. Field of the Disclosure

The technology of the disclosure relates generally to air cavity modules for high-power circuits.

### II. BACKGROUND

Wireless transceivers abound in modern society, ranging from small mobile computing devices such as cell phones and tablets to infrastructure to support cellular communication to radars used for air traffic control, and the like. While the pressure to reduce the size of transceiver components is well documented in the personal mobile communication device market, it should be appreciated that the desire to minimize component size extends through most wireless transceivers. Thus, finding ways to reduce component size provides room for innovation.

### SUMMARY

Aspects disclosed in the detailed description include double-sided high-power modules with an air cavity and methods for forming same. In particular, a module may have a metallization layer having a high-power die on a first side and other components encased in mold material on a second side opposite the first side. Conductors are provided that couple metal conductors in the metallization layer through the mold to an external surface of the mold material such that the module may be electrically coupled to a substrate such as a printed circuit board or the like. By placing components on both sides of the metallization layer, the overall x-y dimensions of the module may be reduced.

In this regard, in one aspect, a module is disclosed. The module includes a metallization layer comprising internal conductors and vias, the metallization layer having a first side in an x-y plane and a second side parallel to and opposite the first side and at least one component mounted on the first side and encapsulated in a mold material. The module also includes a die positioned on the second side and a lid positioned over the die in a z-axis direction and delimiting with the second side an air cavity in which the die is positioned.

In another aspect, a transceiver is disclosed. The transceiver includes a baseband processor (BBP) configured to generate a signal to be amplified and an amplifier chain coupled to the BBP and receiving the signal to be amplified. The amplifier chain includes a module comprising: a metallization layer comprising internal conductors and vias, the metallization layer having a first side in an x-y plane and a second side parallel to and opposite the first side, at least one component mounted on the first side and encapsulated in a mold material, a power amplifier die positioned on the second side; and a lid positioned over the power amplifier die in a z-axis direction and delimiting with the second side an air cavity in which the die is positioned.

In another aspect, a method for forming a module is disclosed. The method includes forming a metallization layer having internal conductors and vias, placing at least one component on a first side of the metallization layer, and placing a die on a second side of the metallization layer. The method also includes electrically coupling the die to at least one internal conductor, applying mold material to encapsulate the at least one component, and attaching a lid to the second side of the metallization layer to form an air cavity containing the die.

### BRIEF DESCRIPTION OF THE DRAWINGS

FIG. 1 is a side cross-sectional view of a conventional module with an air cavity;

FIG. 2 is a side cross-sectional view of a module having components on both sides of a metallization layer according to aspects of the present disclosure;

FIG. 3 is a high-level flowchart for forming the module of FIG. 2 according to aspects of the present disclosure;

FIG. 4 is a flowchart with additional details for forming a first double-sided high-power module with an air cavity according to exemplary aspects of the present disclosure;

FIGS. 5A-5G are side cross-sectional views of intermediate products formed by the process of FIG. 4;

FIG. 5H is a finished module formed according to the process of FIG. 4;

FIG. 6 is a flowchart with additional details for forming a second double-sided high-power module with an air cavity according to exemplary aspects of the present disclosure;

FIGS. 7A-7I are side cross-sectional views of intermediate products formed by the process of FIG. 6;

FIG. 7J is a finished module formed according to the process of FIG. 6;

FIG. 8 is a flowchart with additional details for forming a third double-sided high-power module with an air cavity according to exemplary aspects of the present disclosure;

FIGS. 9A-9I are side-cross-sectional views of intermediate products formed by the process of FIG. 8;

FIG. 9J is a finished module formed according to the process of FIG. 8;

FIG. 10 is a flowchart with additional details for forming a fourth double-sided high-power module with an air cavity according to exemplary aspects of the present disclosure;

FIGS. 11A-11J are side cross-sectional views of intermediate products formed by the process of FIG. 10;

FIG. 11K is a finished module according to exemplary aspects of the present disclosure; and

FIG. 12 is a block diagram of a wireless transceiver, which may include the double-sided module of FIGS. 2-11K according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include double-sided high-power modules with an air cavity and methods for forming same. In particular, a module may have a metallization layer having a high-power die on a first side and other components encased in mold material on a second side opposite the first side. Conductors are provided that couple metal conductors in the metallization layer through the mold to an external surface of the mold material such that the module may be electrically coupled to a substrate such as a printed circuit board or the like. By placing components on both sides of the metallization layer, the overall x-y dimensions of the module may be reduced.

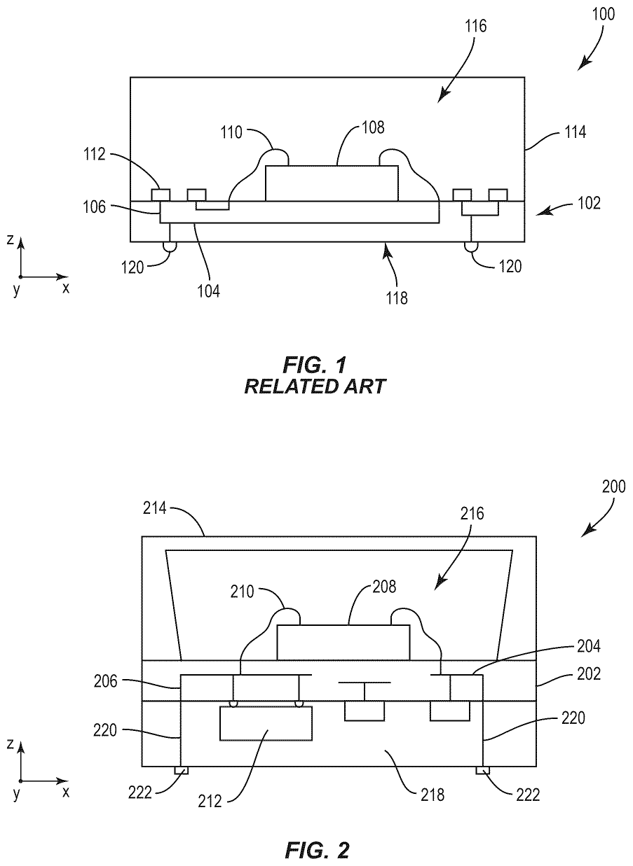

Before addressing aspects of the present disclosure, a brief overview of a conventional air cavity module is provided with reference to FIG. 1. A discussion of aspects of the present disclosure begins below with reference to FIG. 2.

In this regard, FIG. 1 illustrates a conventional air cavity module 100 having a metallization layer 102 with conductors 104 separated by dielectric layers (not labeled) and connected by vertical (in the z-axis) vias 106. A high-power die (e.g., a gallium nitride (GaN) or gallium arsenide (GaAs) power amplifier) 108 may be positioned on a first surface of the metallization layer 102 and coupled to vias 106 and conductors 104 through wirebond connections 110. Other components 112, such as surface mounted inductors/capacitors, digital dies, and the like, may also be positioned on the first surface of the metallization layer 102. A lid 114 covers the metallization layer 102 and creates an air cavity 116 within which the die 108 and the components 112 may be positioned. The bottom side 118 may have input/output (I/O) contact points 120 positioned thereon that allow electrical coupling to vias 106 and conductors 104.

It should be appreciated that having the other components 112 proximate to the die 108 is desirable, but this conventional approach creates a relatively large footprint in the x-y plane. As noted above, the pressure to reduce size conflicts with this large footprint.

Exemplary aspects of the present disclosure contemplate making a double-sided module that positions the high-power die on one side of a metallization layer and places the other components within a mold compound on the other side of the metallization layer. Some form of conductor will extend vertically through the mold compound to an external I/O contact point to allow electrical connection to the conductors and vias in the metallization layer (and thus allow electrical connection to the high-power die and the other components). Stacking components in this sort of double-sided configuration reduces the x-y footprint at a small z-axis penalty, which is an acceptable compromise for many designs.

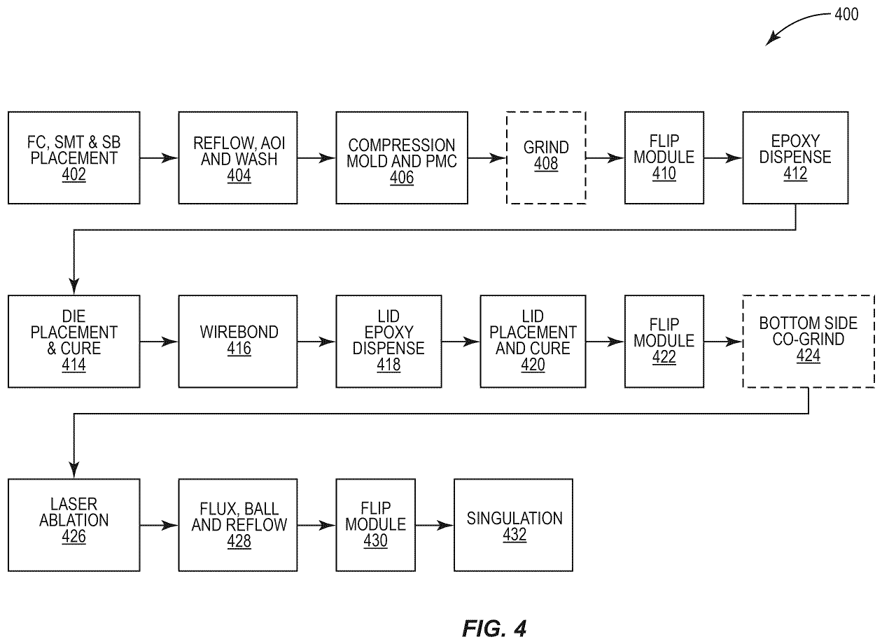

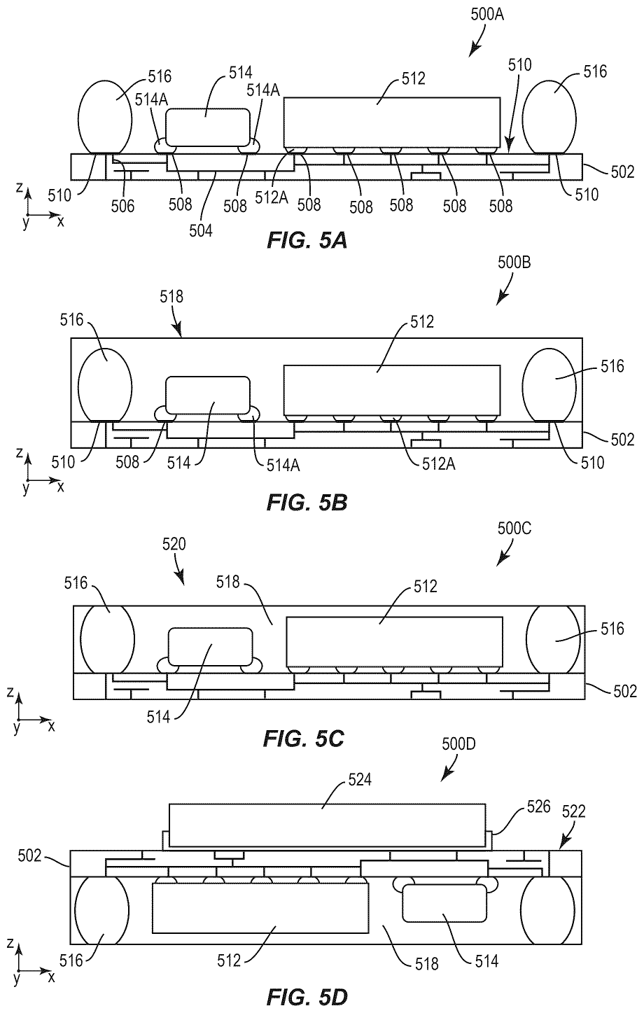

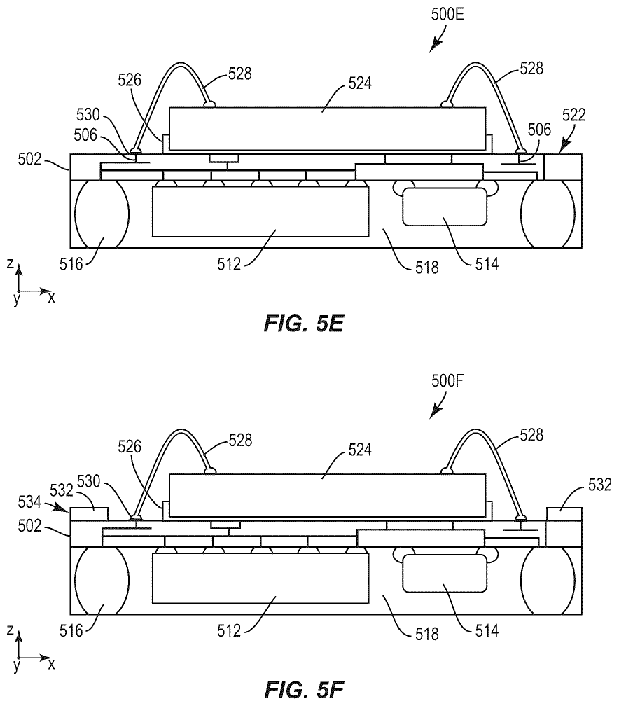

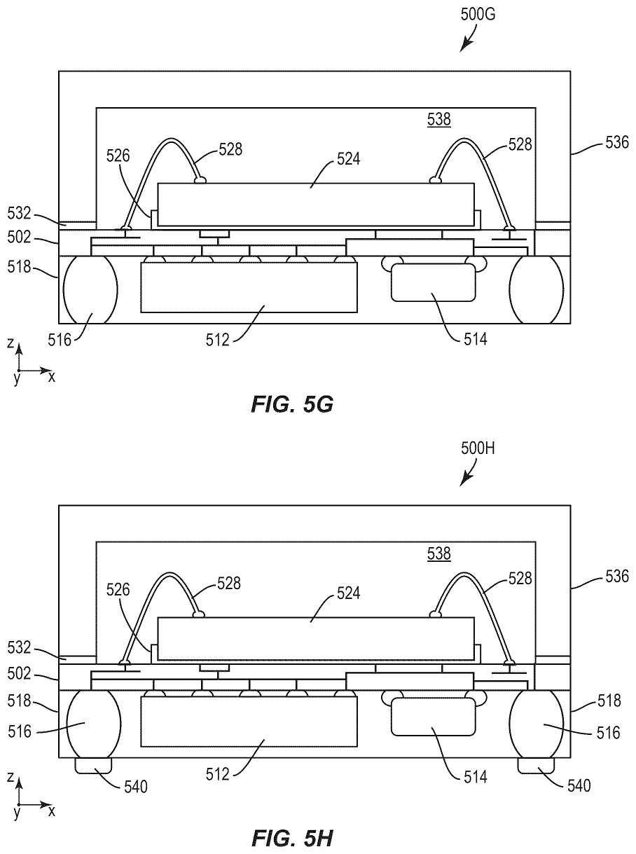

In this regard, FIG. 2 provides a generic view of a module 200 according to aspects of the present disclosure, while FIGS. 5H, 7J, 9J, and 11K illustrate specific aspects based on formation processes set forth in FIGS. 4, 6, 8, and 10.

With reference to FIG. 2, the module 200 includes a metallization layer 202 having conductors 204 and vias 206 therein surrounded by dielectric material (not specifically labeled). A high-power die (e.g., a gallium nitride (GaN) or gallium arsenide (GaAs) power amplifier) 208 may be positioned on a first surface of the metallization layer 202 and coupled to vias 206 and conductors 204 through wirebond connections 210.

Unlike the module 100, in the module 200, other components 212, such as surface-mounted inductors/capacitors, digital dies, and the like are positioned on a second surface opposite the first surface (in the z-axis) of the metallization layer 202. A lid 214 covers the metallization layer 202 and creates an air cavity 216 within which the die 208 is positioned. That is, the lid 214 is positioned over the die 208 (in the z-axis direction). The other components 212 may be encased in a mold compound or mold material 218. Conductors 204 and vias 206 couple to vertical conductors 220 that extend through the mold material 218 to external I/O contact points 222. The external I/O contact points 222 are configured to couple to conductors on a substrate such as a PCB or the like.

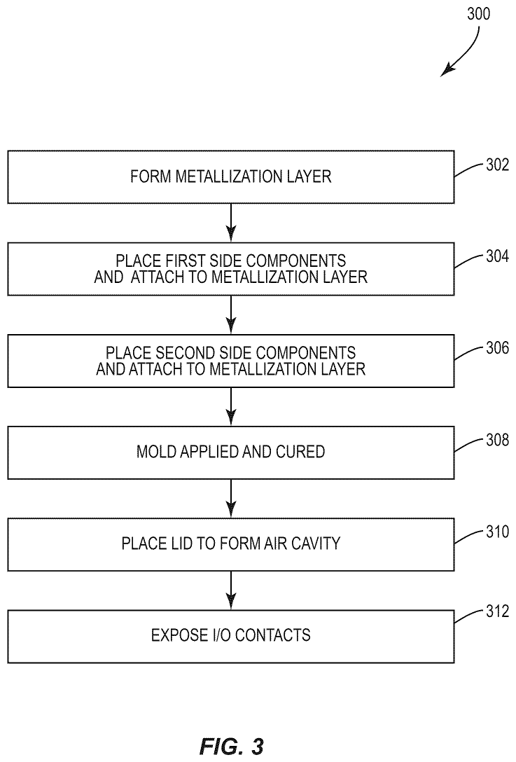

With the understanding that subsequent Figures provide specific methods that customize the nature of the external I/O contact points, the vertical conductors, and the like, FIG. 3 sets forth a generic process 300 for forming a module according to aspects of the present disclosure.

In this regard, the process 300 begins by forming a metallization layer (block 302). The internal metal conductors and vias are arranged such that there are I/O points on both sides (in the z-axis direction) configured to be coupled to wirebonds, die bumps, or the like of high-power dies and other components. First component(s) (e.g., the high-power die or the other components) is placed on the first side and attached to the metallization layer (block 304) such that the I/O points are electrically coupled to internal circuits within the first components. Second component(s) is then placed on the second side and attached to the metallization layer (block 306) such that the I/O points on the second side are electrically coupled to internal circuits in the second components. Mold is applied and cured (block 308) to cover and encapsulate the other components. The lid is placed to form the air cavity (block 310). The mold compound is then ground to expose one end of vertical conductors to form the I/O contacts (block 312).

While the generic description of FIGS. 2 and 3 is accurate and shows the breadth of the present disclosure, FIGS. 4-11K illustrate more specific aspects. In this regard, FIG. 4 is a flowchart of a process 400 that makes a first aspect and references FIGS. 5A-5G to illustrate specific steps of the process 400 culminating in a finished product 500H illustrated in FIG. 5H.

In this regard, the process 400 begins by forming the metallization layer 502 with its internal conductors 504 (x-y dimensions) and vias 506 (z-dimension) having the desired routing connections established. At least some of the vias 506 terminate with surface contacts 508 on a first side 510 (as shown a top side in the z-axis). It should be appreciated that the metallization layer 502 may initially be a large sheet in the x-y dimensions for later singulation (see block 432 below). To this metallization layer 502, a flip chip 512, a surface mounted technology (SMT) element 514 (e.g., inductors, capacitors, or the like), and solder balls 516 are placed and attached (block 402 FIG. 5A), making electrical connections between, for example, die bumps 512A, 514A and the surface contacts 508 to form intermediate product 500A. The solder balls 516 are conductive and may be directly electrically coupled to the surface contacts 508 of the metallization layer 502.

The process 400 continues with a reflow, automated optical inspection (AOI), and wash (block 404) to clean up the first side of the metallization layer 502 and its attached elements. The elements are then encapsulated in a mold material 518 through a compression mold and post-mold cure (PMC) (block 406, FIG. 5B) to form intermediate product 500B. Optionally, the intermediate product 500B may have surface 520 ground (and maybe chemical mechanical polished (CMP)) to expose the solder balls 516 (block 408, FIG. 5C) to form intermediate product 500C. This step is optional to the extent that it can be done later (see block 424 below).

The intermediate product 500C is flipped (block 410), and then an epoxy (sometimes referred to as a die attach epoxy) dispensed (block 412) on a second side 522 of the metallization layer 502. A die 524 is then placed on the epoxy 526 and the epoxy 526 is cured (block 414, FIG. 5D) to form intermediate product 500D. In an exemplary aspect, the die 524 is a high-power die such as a power amplifier. In a further exemplary aspect, the die 524 is pressed down into the epoxy 526 before curing such that the epoxy 526 adheres not just to a bottom side of the die 524, but also to vertical sides of the die 524 (z-axis).

Wirebonds 528 are then used to couple the die 524 to surface contacts 530 on the second side 522 of the metallization layer 502 (block 416, FIG. 5E) to form intermediate product 500E. The surface contacts 530 couple to one or more vias 506 in the metallization layer 502. A lid epoxy 532 is then dispensed (block 418, FIG. 5F) to form intermediate product 500F. The lid epoxy 532 may be positioned at a circumferential edge 534 of the metallization layer 502 on the second side 522.

A lid 536 is then placed on the lid epoxy 532, and the lid epoxy 532 is cured (block 420, FIG. 5G) to form intermediate product 500G. The lid 536 may be made from a material such as FR4 or liquid crystal polymer (LCP) and may, as illustrated, be generally rectilinear, having a top and sidewalls. Placement of the lid 536 forms the air cavity 538 around the die 524.

The intermediate product 500G is then flipped (block 422) and if the surface 520 was not already ground at block 408, the surface 520 is now ground (block 424) to expose the solder balls 516. A laser ablation process is performed to expose more of the solder balls 516 (block 426), and then a flux is applied to the solder balls 516 and reflowed (block 428) to form better solder ball contact pads 540. The module is now almost complete and flipped (block 430) and singulated (block 432) to form finished module 500H illustrated in FIG. 5H.

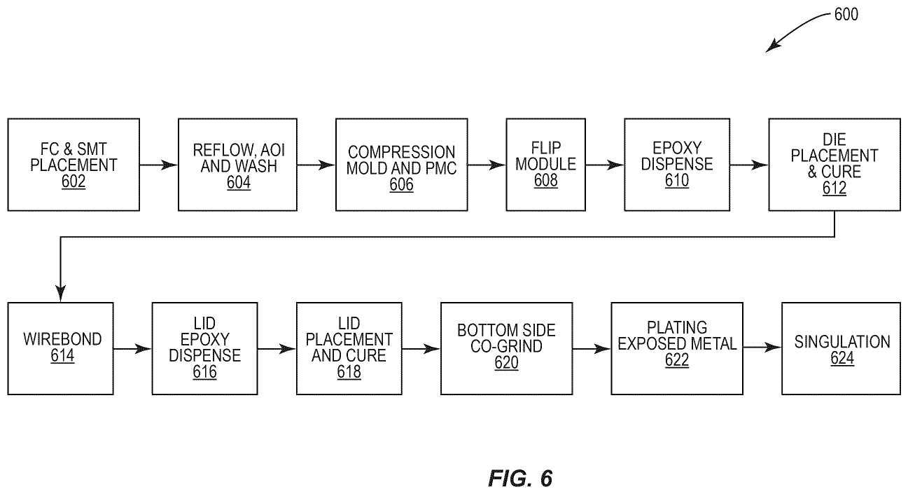

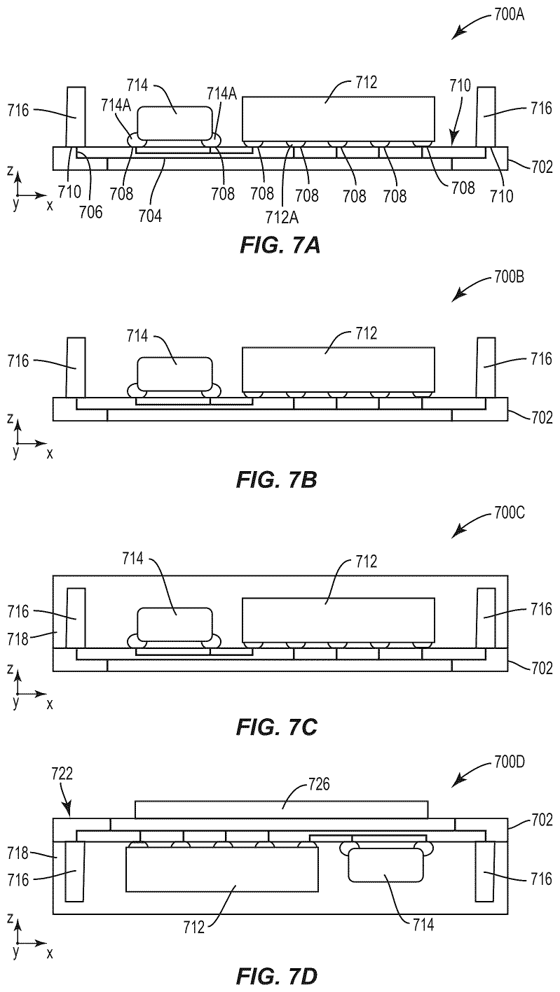

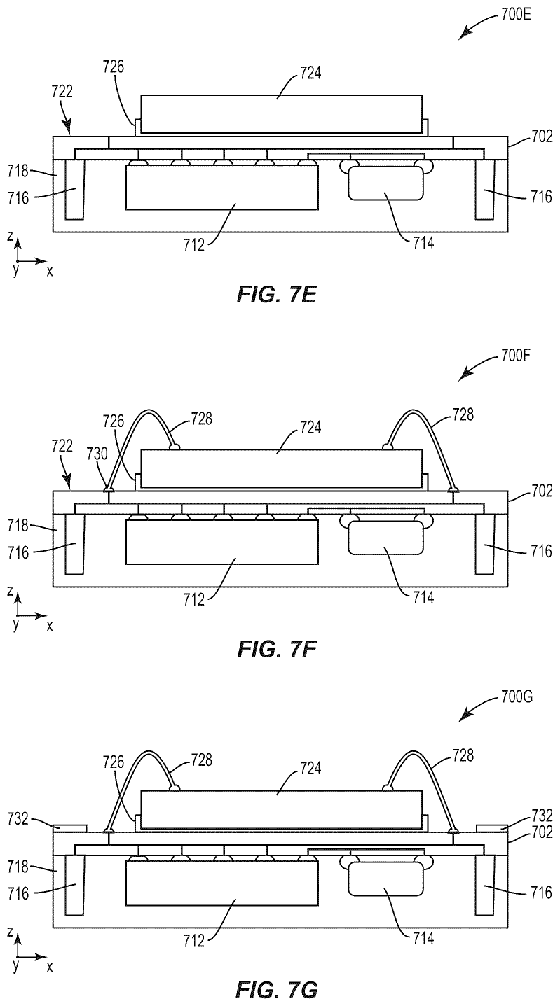

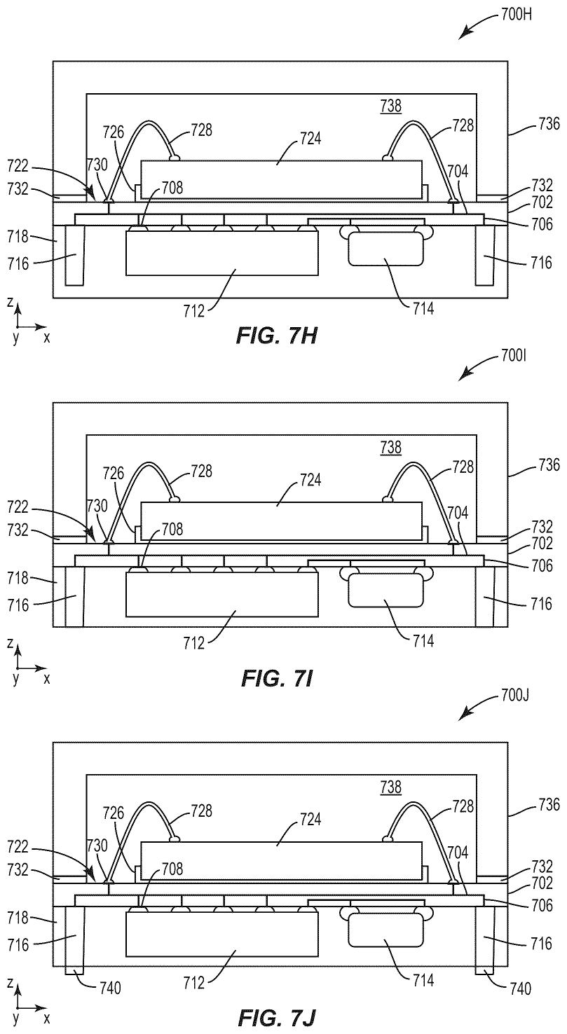

Solder balls are a well-established form of connecting a module, such as module 500H to another laminate substrate, but there are other structures that may equivalently be used. For example, a land grid array may be used with conductive metallic posts extending from the metallization layer to an exposed external contact in place of the solder balls. A process 600 for forming such a finished product is set forth in FIG. 6 with reference to FIGS. 7A-7I, showing intermediate products culminating in a finished module 700J in FIG. 7J.

In this regard, the process 600 begins by forming the metallization layer 702 with its internal conductors 704 (x-y dimensions) and vias 706 (z-dimension) having the desired routing connections established. At least some of the vias 706 terminate with surface contacts 708 on a first side 710 (as shown a top side in the z-axis). It should be appreciated that the metallization layer 702 may initially be a large sheet in the x-y dimensions and that includes posts 716 (part of a land grid array) for later singulation (see block 624 below). To this metallization layer 702, a flip chip 712, a surface mounted technology (SMT) element 714 (e.g., inductors, capacitors, or the like), and the like are placed and attached (block 602, FIG. 7A), making electrical connections between, for example, die bumps 712A, 714A and the surface contacts 708 to form intermediate product 700A. The posts 716 are conductive and may be directly electrically coupled to the surface contacts 708 of the metallization layer 702.

The process 600 continues with a reflow, automated optical inspection (AOI), and wash (block 604, FIG. 7B) to clean up the first side of the metallization layer 702 and its attached elements. The elements are then encapsulated in a mold material 718 through a compression mold and PMC (block 606, FIG. 7C) to form intermediate product 700C.

The intermediate product 700C is flipped (block 608) and then an epoxy 726 (sometimes referred to as a die attach epoxy) dispensed (block 610, FIG. 7D) on a second side 722 of the metallization layer 702 to form an intermediate product 700D. A die 724 is then placed on the epoxy 726, and the epoxy 726 is cured (block 612, FIG. 7E) to form intermediate product 700E. In an exemplary aspect, the die 724 is a high-power die such as a power amplifier. In a further exemplary aspect, the die 724 is pressed down into the epoxy 726 before curing such that the epoxy 726 adheres not just to a bottom side of the die 724, but also to vertical sides of the die 724 (z-axis).

Wirebonds 728 are then used to couple the die 724 to surface contacts 730 on the second side 722 of the metallization layer 702 (block 614, FIG. 7F) to form intermediate product 700F. The surface contacts 730 couple to one or more vias 706 in the metallization layer 702. A lid epoxy 732 is then dispensed (block 616, FIG. 7G) to form intermediate product 700G. The lid epoxy 732 may be positioned at a circumferential edge 734 of the metallization layer 702 on the second side 722.

A lid 736 is then placed on the lid epoxy 732 and the lid epoxy 732 is cured (block 618, FIG. 7H) to form intermediate product 700H. The lid 736 may be made from a material such as FR4 or LCP. Placement of the lid 736 forms the air cavity 738 around the die 724.

The intermediate product 700H may then undergo back-side grinding (block 620, FIG. 7I) to expose the posts 716. The posts 716 may initially be copper are then plated with metal (e.g., nickel/gold or nickel/lead/gold) 740 (block 622). The module singulated (block 624) to form finished module 700J illustrated in FIG. 7J.

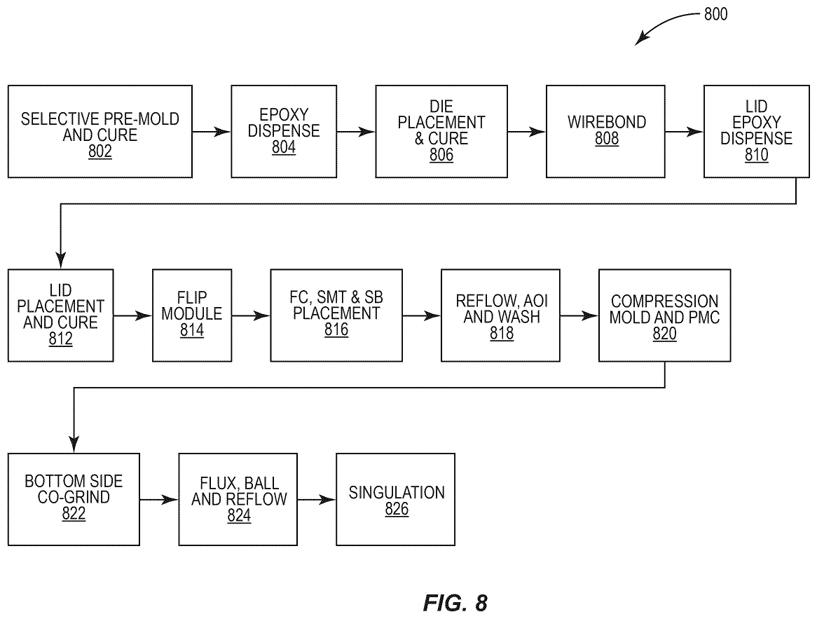

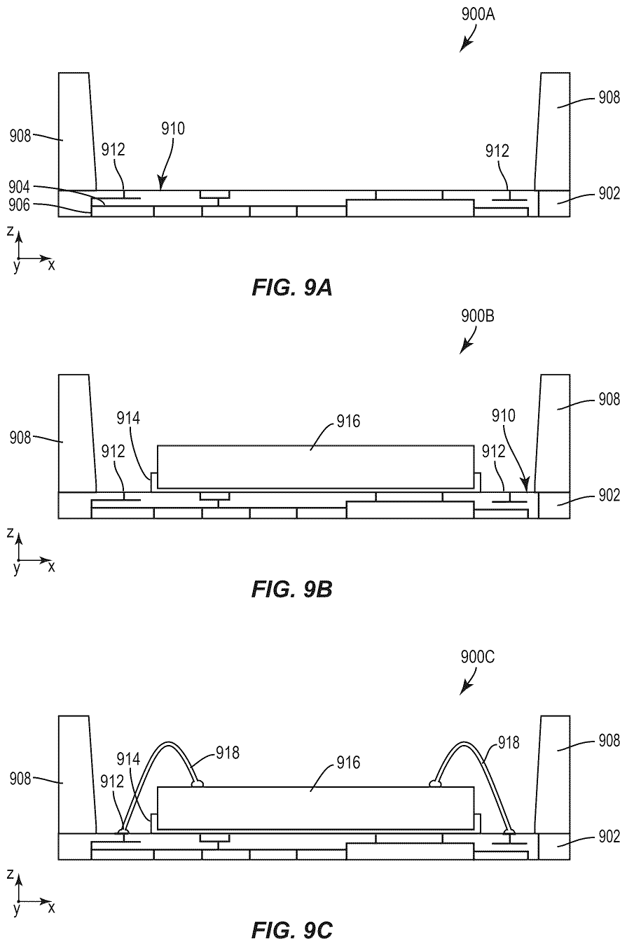

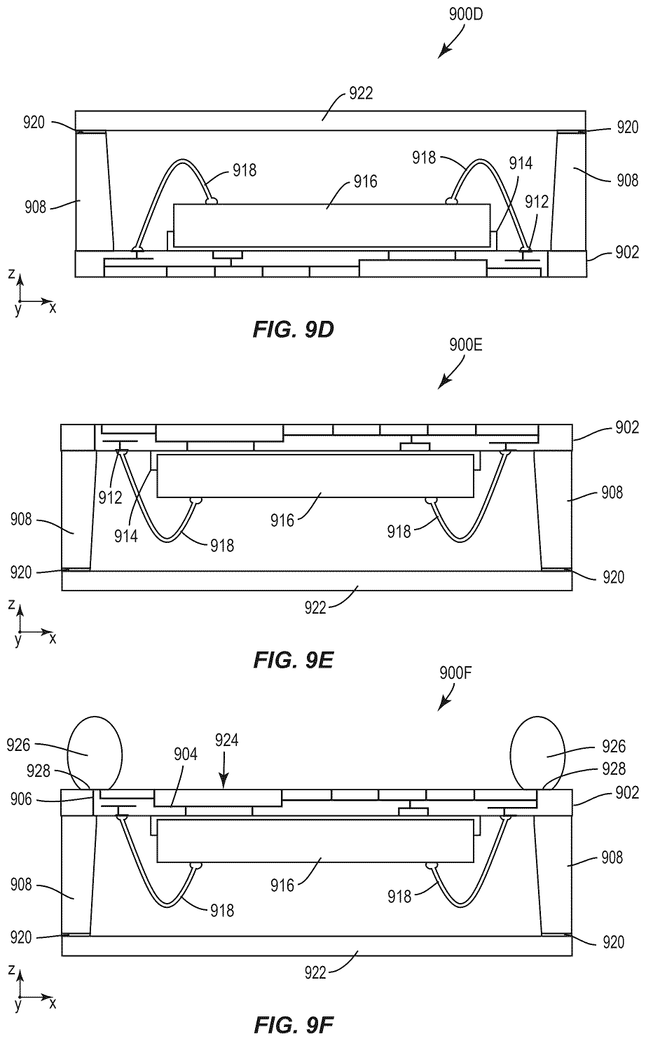

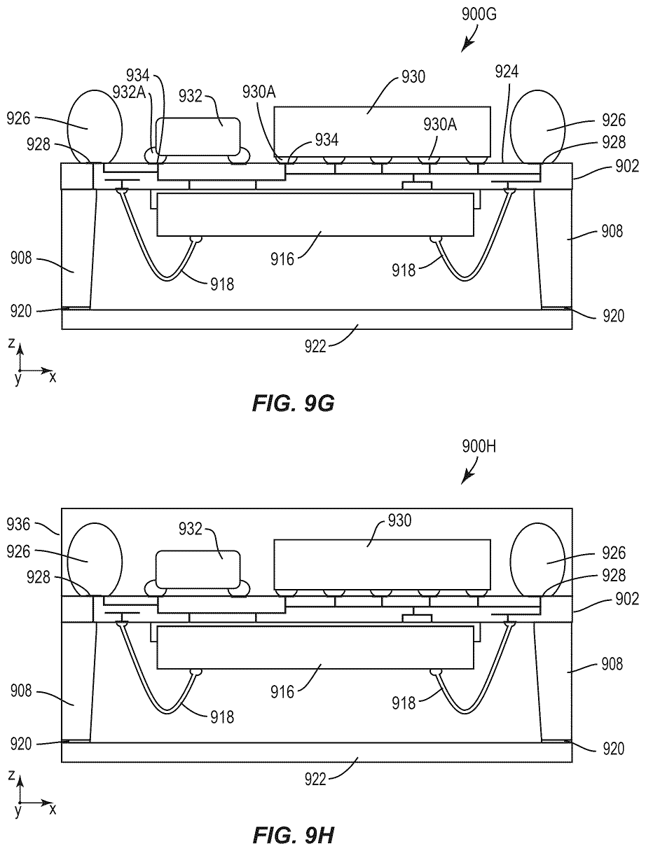

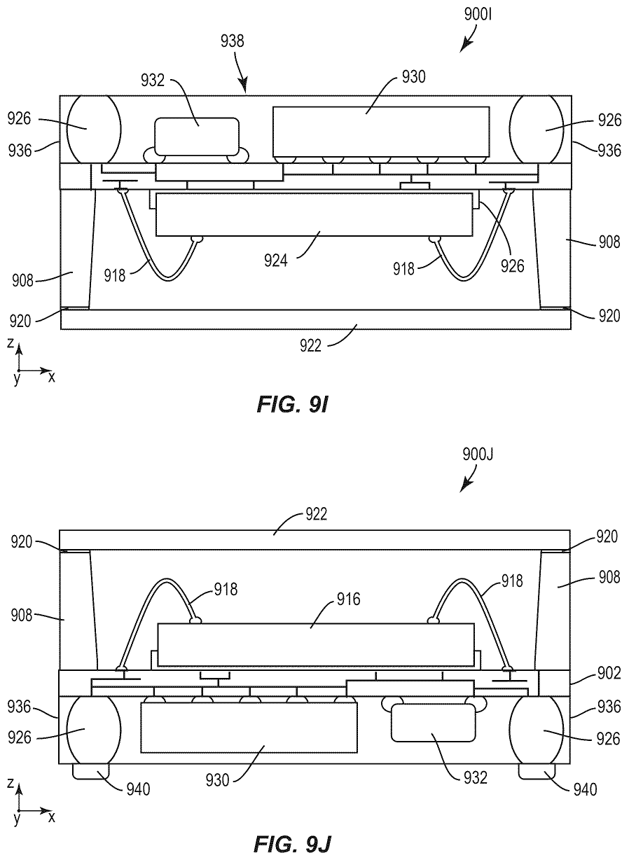

The processes 400 and 600 have started with the non-air cavity side of the module. The present disclosure is not so limited and the air cavity can be formed first, as illustrated by a process 800 in FIG. 8. FIGS. 9A-9I show intermediate products 900A-900I to help illustrate the process 800, culminating in the finished module 900J, illustrated in FIG. 9J.

In this regard, the process 800 begins with forming the metallization layer 902 with internal conductors 904 and vias 906 with dielectric material as previously discussed. Mold material sidewalls 908 are applied to a first surface 910 of the metallization layer 902. Contacts 912 are present on the first surface 910 and electrically connected to the conductors 904 and vias 906. After the mold material sidewalls 908 are applied, the mold material is cured (block 802, FIG. 9A) to form intermediate product 900A. A die attach epoxy 914 is applied to the first surface 910 (block 804). A die 916 is then placed in the die attach epoxy 914 and the die attach epoxy 914 is cured (block 806, FIG. 9B) to form intermediate product 900B.

Wirebonds 918 are then used to couple electrically the die 916 to the contacts 912 (block 808, FIG. 9C) to form intermediate product 900C. A lid epoxy 920 is dispensed (block 920) on the material sidewalls 908 and a lid 922 is attached by curing the lid epoxy 920 (block 812, FIG. 9D) to form intermediate product 900D. The intermediate product 900D is flipped (block 814, FIG. 9E) through the x-y plane to form inverted intermediate product 900D.

The other side 924 is now populated by placing solder balls 926 (FIG. 9F) to form intermediate product 900F. The solder balls 926 are electrically coupled to the conductors 904 and material sidewalls 908 through contacts 928. A flip chip die 930, and SMT element 932 are then placed on the other side 924 (block 916, FIG. 9G) to form intermediate product 900G. Die bumps 930A, 932A may couple to contacts 934 on the surface of other side 924 to couple the die 930, SMT element 932 to the conductors 904 and vias 906. The other side 924 may be subjected to a reflow, AOI, and wash (block 818) to clean that side.

The process 800 continues by adding a mold material 936 and PMC (block 820, FIG. 9H) to form intermediate product 900H. The mold material 936 may be applied through a compression mold technique. A surface 938 is then ground (block 822, FIG. 9I) to expose the solder balls 926 and form intermediate product 900I. There may be laser ablation to expose more of the solder balls 926 followed by flux application and reflow to form contacts 940 (block 824) and then a flip and singulation (block 826, FIG. 9J) to form finished module 900J.

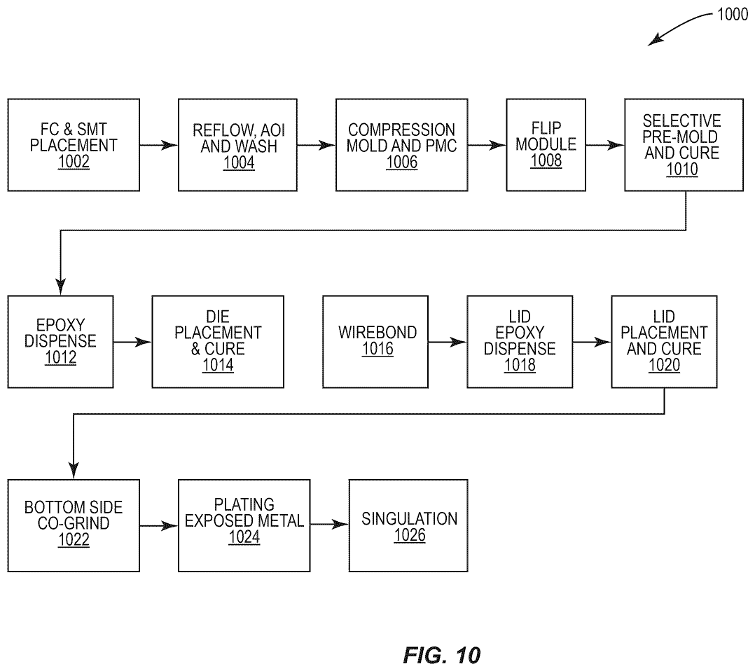

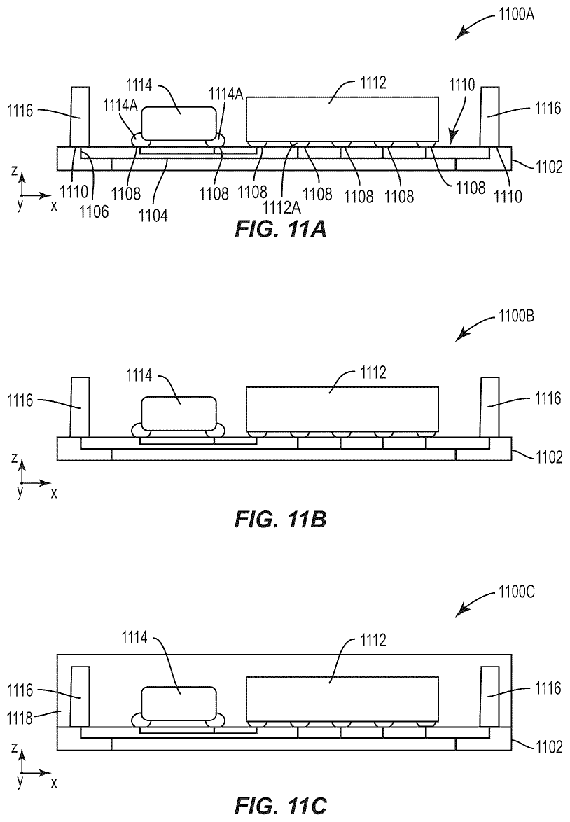

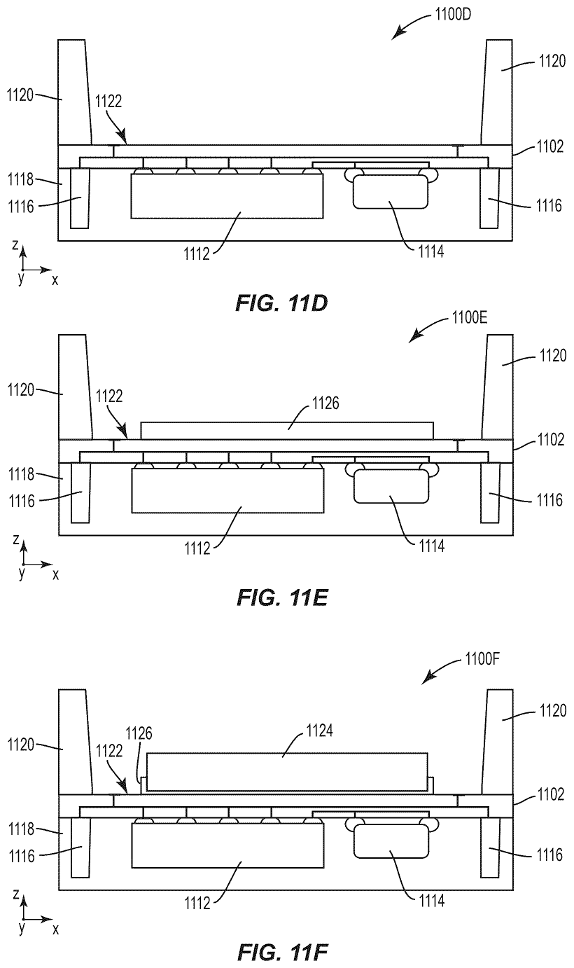

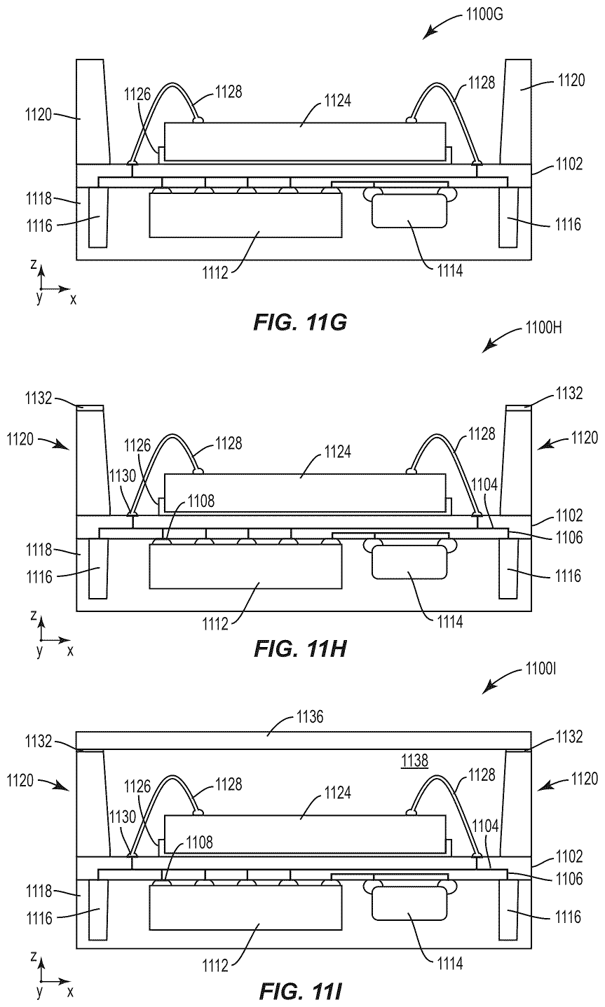

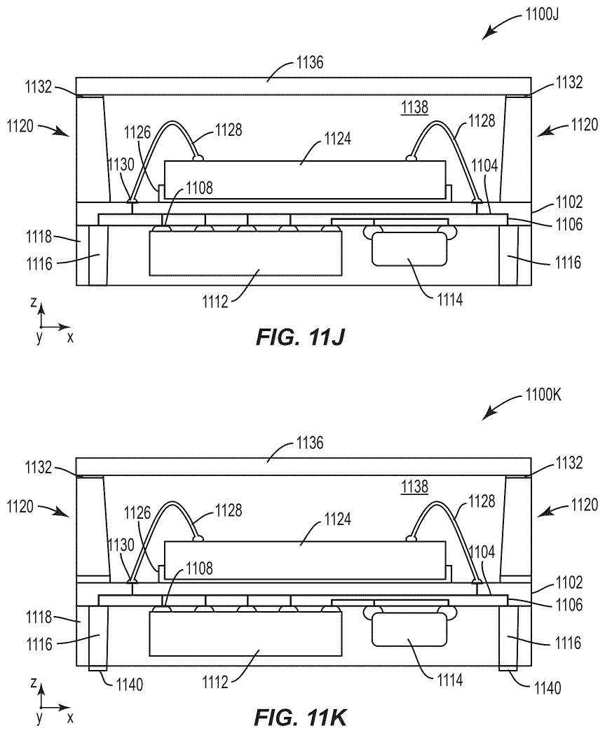

FIG. 10 provides a flowchart for forming a module that is a hybrid of the finished module 900J and 700J in that it has the land grid array of module 700J, but the air cavity of module 900J. In this regard, the process 1000 begins by forming the metallization layer 1102 with its internal conductors 1104 (x-y dimensions) and vias 1106 (z-dimension) having the desired routing connections established. At least some of the vias 1106 terminate with surface contacts 1108 on a first side 1110 (as shown a top side in the z-axis). It should be appreciated that the metallization layer 1102 may initially be a large sheet in the x-y dimensions with posts 1116 (for the land grid array) for later singulation (see block 1024 below). To this metallization layer 1102, a flip chip 1112, a surface mounted technology (SMT) element 1114 (e.g., inductors, capacitors, or the like), and the like are placed and attached (block 1002, FIG. 11A), making electrical connections between, for example, die bumps 1112A, 1114A and the surface contacts 1108 to form intermediate product 1100A. The posts 1116 are conductive and may be directly electrically coupled to the surface contacts 1108 of the metallization layer 1102.

The process 1000 continues with a reflow, automated optical inspection (AOI), and wash (block 1004, FIG. 11B) to clean up the first side of the metallization layer 1102 and its attached elements. The elements are then encapsulated in a mold material 1118 through a compression mold and PMC (block 1006, FIG. 11C) to form intermediate product 1100C.

The intermediate product 1100C is flipped (block 1008) and sidewalls 1120 are formed from mold material (block 1010, FIG. 11D) on a second side 1122 of the metallization layer 1102 to form an intermediate product 1100D. Die attach epoxy 1126 is then dispensed (block 1012, FIG. 11E) on the second side 1122 to form intermediate product 1100E. A die 1124 is then placed on the die attach epoxy 1126, and the die attach epoxy 1126 is cured (block 1014, FIG. 11F) to form intermediate product 1100F. In an exemplary aspect, the die 1124 is a high-power die such as a power amplifier. In a further exemplary aspect, the die 1124 is pressed down into the die attach epoxy 1126 before curing such that the die attach epoxy 1126 adheres not just to a bottom side of the die 1124, but also to vertical sides of the die 1124 (z-axis).

Wirebonds 1128 are then used to couple the die 1124 to surface contacts 1130 on the second side 1122 of the metallization layer 1102 (block 1016, FIG. 11G) to form intermediate product 1100G. The surface contacts 1130 couple to one or more vias 1106 in the metallization layer 1102. A lid epoxy 1132 is then dispensed (block 1018, FIG. 11H) to form intermediate product 1100H. The lid epoxy 1132 may be positioned on top of the sidewalls 1120.

A lid 1136 is then placed on the lid epoxy 1132, and the lid epoxy 1132 is cured (block 1020, FIG. 11I) to form intermediate product 1100I. The lid 1136 may be made from a material such as FR4 or LCP. Placement of the lid 1136 forms the air cavity 1138 around the die 1124. The intermediate product 1100I may then undergo back-side grinding (block 1022, FIG. 11J) to expose the posts 1116. The posts 1116 are then plated with metal (e.g., nickel/gold or nickel/lead/gold) 1140 (block 1024). The module singulated (block 1026) to form finished module 1100K, illustrated in FIG. 11K.

The double-sided high-power modules with an air cavity, according to aspects disclosed herein, are specifically contemplated for use in infrastructure-type devices, including base stations, radar transceivers, or the like. Such devices utilize the high-power power amplifiers that operate better in an air cavity and generally have the vertical space (z-axis) available to accommodate the larger vertical size of air cavity modules. While this infrastructure focus can see immediate application of the concepts disclosed herein, the present disclosure is not strictly limited to such deployments and may, in time, be provided in or integrated into any processor-based device including more end or home consumer-focused devices. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

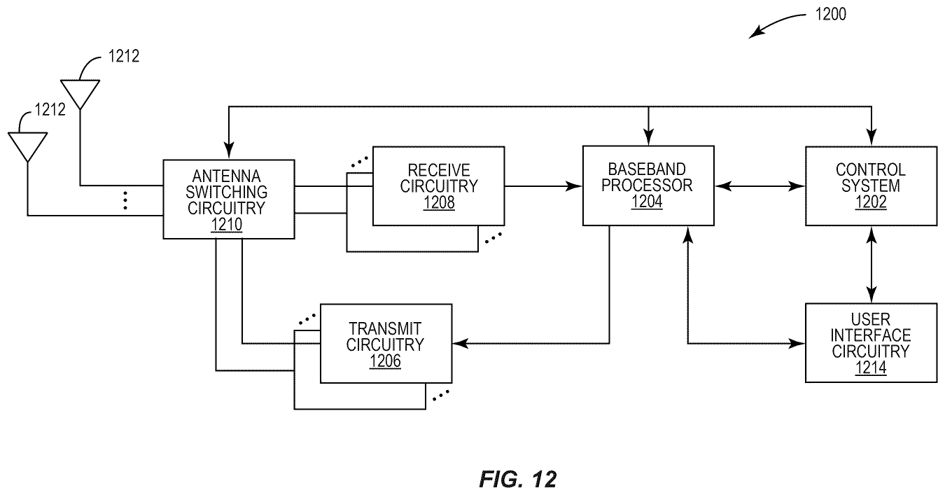

FIG. 12 is a schematic diagram of an exemplary communication device 1200 wherein the included double-sided high-power modules with an air cavity can be provided. Herein, the communication device 1200 can be any type of communication device wired or wireless, such as those listed above, as well as access points, base stations (e.g., eNB or gNB), radar, and any other type of wireless communication devices that support wireless communications, such as cellular, wireless local area network (WLAN), Bluetooth, Ultra-wideband (UWB), and near field communications. While implementing the concepts of the present disclosure into consumer electronic devices is currently impractical, such a use may become practical at a later date, and the present disclosure contemplates such use.

More particularly, the communication device 1200 will generally include a control system 1202, a baseband processor 1204, transmit circuitry 1206, receive circuitry 1208, antenna switching circuitry 1210, multiple antennas 1212, and user interface circuitry 1214. In a non-limiting example, the control system 1202 can be a field-programmable gate array (FPGA) or an application-specific integrated circuit (ASIC), as an example. In this regard, the control system 1202 can include at least a microprocessor(s), an embedded memory circuit(s), and a communication bus interface(s). The receive circuitry 1208 receives radio frequency signals via the antennas 1212 and through the antenna switching circuitry 1210 from one or more base stations. A low noise amplifier and a filter of the receive circuitry 1208 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1204 processes the digitized received signal to extract the information or data bits conveyed in the received signal. This processing typically comprises demodulation, decoding, and error correction operations. The baseband processor 1204 is generally implemented in one or more digital signal processors (DSPs) and ASICs.

For transmission, the baseband processor 1204 receives digitized data, which may represent voice, data, or control information, from the control system 1202, which it encodes for transmission. The encoded data is output to the transmit circuitry 1206, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1212 through the antenna switching circuitry 1210. It is this power amplifier that is likely to be the high-power die used in the air cavity modules of the present disclosure. The multiple antennas 1212 and the replicated transmit and receive circuitries 1206, 1208 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A module comprising:
a metallization layer comprising internal conductors and vias, the metallization layer having a first side in an x-y plane and a second side parallel to and opposite the first side;
at least one component mounted on the first side and encapsulated in a mold material;
a die positioned on the second side; and
a lid positioned over the die in a z-axis direction and delimiting with the second side an air cavity in which the die is positioned.

2. The module of claim 1, further comprising an external contact positioned on an exterior surface of the mold material, the external contact electrically coupled to at least one of the internal conductors.

3. The module of claim 2, wherein the external contact comprises a solder ball.

4. The module of claim 2, wherein the external contact comprises a conductive post.

5. The module of claim 1, wherein the at least one component comprises a flip chip die.

6. The module of claim 1, further comprising wirebonds electrically coupling the die to at least one conductor in the metallization layer.

7. The module of claim 1, further comprising a die-attach epoxy coupling the die to the second side.

8. The module of claim 1, further comprising a sidewall positioned on the second side, the sidewall comprising a second mold material, wherein the lid is attached to the sidewall.

9. The module of claim 1, wherein the at least one component comprises a surface-mounted technology component.

10. The module of claim 1, wherein the at least one component is electrically coupled to at least one conductor in the metallization layer.

11. The module of claim 1, wherein the lid comprises a cup-shaped lid that has a top and sidewalls.

12. A transceiver comprising:
a baseband processor (BBP) configured to generate a signal to be amplified;
an amplifier chain coupled to the BBP and receiving the signal to be amplified, the amplifier chain comprising:
a module comprising:
a metallization layer comprising internal conductors and vias, the metallization layer having a first side in an x-y plane and a second side parallel to and opposite the first side;
at least one component mounted on the first side and encapsulated in a mold material;
a power amplifier die positioned on the second side; and
a lid positioned over the power amplifier die in a z-axis direction and delimiting with the second side an air cavity in which the power amplifier die is positioned.

13. A method for forming a module comprising:
forming a metallization layer having internal conductors and vias;
placing at least one component on a first side of the metallization layer;
placing a die on a second side of the metallization layer;
electrically coupling the die to at least one internal conductor;
applying mold material to encapsulate the at least one component; and
attaching a lid to the second side of the metallization layer to form an air cavity containing the die.

14. The method of claim 13, wherein electrically coupling eh die comprises using wirebonds to couple the die to a surface contact on the second side.

15. The method of claim 13, further comprising forming sidewalls on the second side and attaching the lid to the sidewalls.

16. The method of claim 13, further comprising applying a die-attach epoxy to attach the die to the second side.

17. The method of claim 13, further comprising providing external contacts on an external surface of the mold material.

18. The method of claim 17, wherein providing external contacts comprises providing a solder ball.

19. The method of claim 17, wherein providing external contacts comprises providing at least one conductive post.

20. The method of claim 17, further comprising grinding the mold material to expose a conductive material to form the external contacts.
